(19) United States
(12) Patent Application Publication
(10) Pub. No.: US 2005/0040421 A1
(43) Pub. Date: Feb. 24, 2005

(54) Light-emitting semiconductor device

(75) Inventor: Chung Yu Wu, Hsin-Chu (TW)

Correspondence Address: BACON & THOMAS, PLLC, 625 SLATERS LANE, FOURTH FLOOR, ALEXANDRIA, VA, 22314, US

(73) Assignee: Macroblock, Inc., Hsin-Chu (TW)

(21) Appl. No.: 10/647,257

(22) Filed: Aug. 26, 2003

(30) Foreign Application Priority Data
Aug. 8, 2003 (CN) 092121762

(51) Int. Cl. H01L 33/00

(52) U.S. Cl. 257/99

(57) ABSTRACT

The present invention discloses a light-emitting device, in which at least one light emitting diode and a driver integrated circuit chip are integrally packaged. The driver chip provides a constant current output to the light emitting diode based on characteristics thereof. Accordingly, brightness of the light emitting diode can be precisely adjusted.

### BACKGROUND OF THE INVENTION

1. Field of the Invention

The present invention relates to a light-emitting semiconductor device, in which the light emitting diodes received a constant current unaffected by forward voltage thereof. The present invention is suitable for being applied to back light sources of liquid crystal displays and illumination of variable colors.

2. Related Prior Art

For LEDs, variation of forward voltages is a problem in manufacturing. Even though LEDs of the same color might perform different brightness and are difficult to be controlled.

Currently, in order to make brightness of LEDs identical or vary brightness thereof, a resistor is provided to be connected to each LED and then adjusted according to forward voltage of the respective LED. It apparently requires much effort.

Therefore, it's necessary to provide a light emitting device unaffected by forward voltage of LEDs.

### SUMMARY OF THE INVENTION

The object of the present invention is to provide a light-emitting semiconductor device, which is capable of precisely controlling brightness of LEDs and suitable for mass production.

In order to achieve the above object, the light-emitting semiconductor device primarily includes at least two terminals, at least one LED die, a driver IC chip, a substrate, and a refractive encapsulation material.

Each LED die includes two electrode contacts, one of which is connected to one of the terminals of the light-emitting semiconductor device by an electrically conductive means. The driver IC chip also includes a contact connected to another terminal of the semiconductor device and provides at least one output port.

Both of the LED die and the driver IC chip are attached on the substrate and then integrally encapsulated and protected with the refractive encapsulation material. The LED die and the driver IC chip are connected to each other by an electrically conductive means. In general, another electrode contact of each LED die is connected to the respective output port of the driver IC chip.

Accordingly, the LED can be lit by applying the terminals of the semiconductor device with voltage or current which then flows through the driver IC chip to drive the LED.

The light-emitting semiconductor device of the present invention can be further attached to an application board by adhering the terminals thereon with surface-mount technology or through-hole technology. The current of each output port of the driver IC chip can be preset for adjusting brightness of the corresponding LED. Moreover, regardless of deviation of the forward voltage, the preset current can be kept constant.

In addition to the terminals and contact aforementioned, the light-emitting semiconductor device and the driver IC chip may further respectively include a third terminal and another contact, which are connected to each other by an electrically conductive means. Therefore, the current of the outputs of the driver IC chip can be specifically controlled by current or voltage passing through the third terminal.

### BRIEF DESCRIPTION OF THE DRAWINGS

FIGS. 1 and 2 are a cross section and a schematic view of the light-emitting semiconductor device in accordance with the present invention.

FIGS. 3-6 show electrical connection of four preferred embodiments in accordance with the present invention.

FIGS. 7 and 8 are block diagrams of the circuits in FIGS. 5 and 6.

### DETAILED DESCRIPTION OF THE PREFERRED EMBODIMENTS

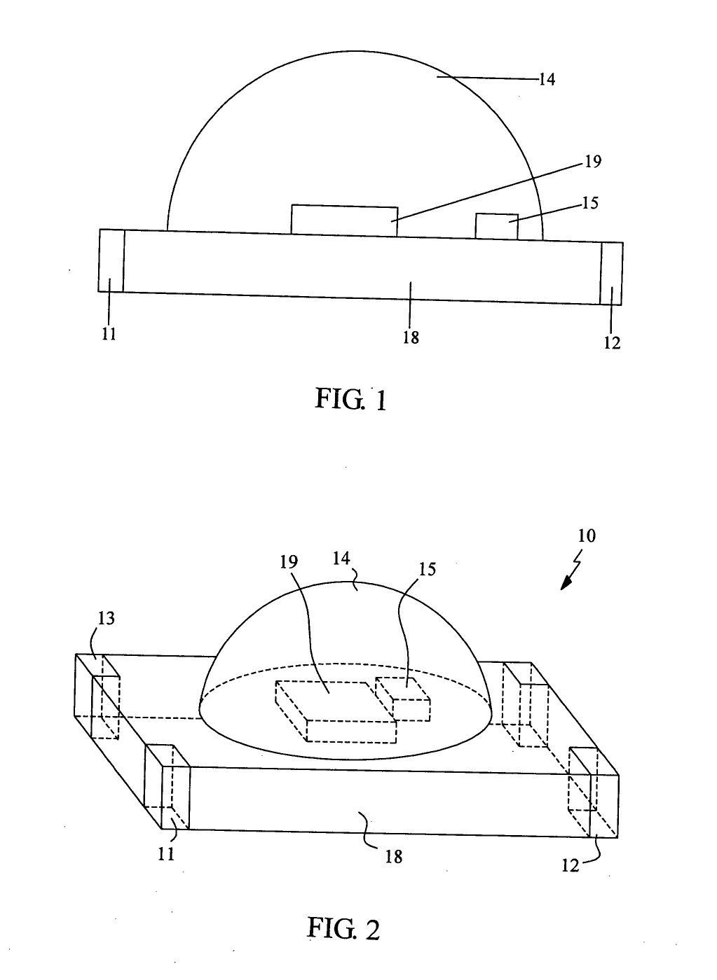

FIGS. 1 and 2 are a cross section and a schematic view of a light-emitting semiconductor device 10 in accordance with the present invention. As shown in FIGS. 1 and 2, the light-emitting device 10 includes one LED die 15, refractive encapsulation material 14, a substrate 18 and a current-driving IC chip 19.

The LED die 15 and the current-driving IC chip 19 are attached to the substrate 18 on which necessary electrically conductive means is arranged as a printed circuit board (PCB). The light-emitting device 10 can be further attached on an application board (not shown in the drawings) by adhering a first terminal 11 and a second terminal 12 thereon with surface mount technology or though-hole technology.

The present invention is primarily characterized by packaging the LED die 15 and the current-driving IC chip 19 integrally in the encapsulation material 14. The encapsulation material 14 can refract light beams emitted from the LED die 15 toward a predetermined direction, and ordinarily off the device 10.

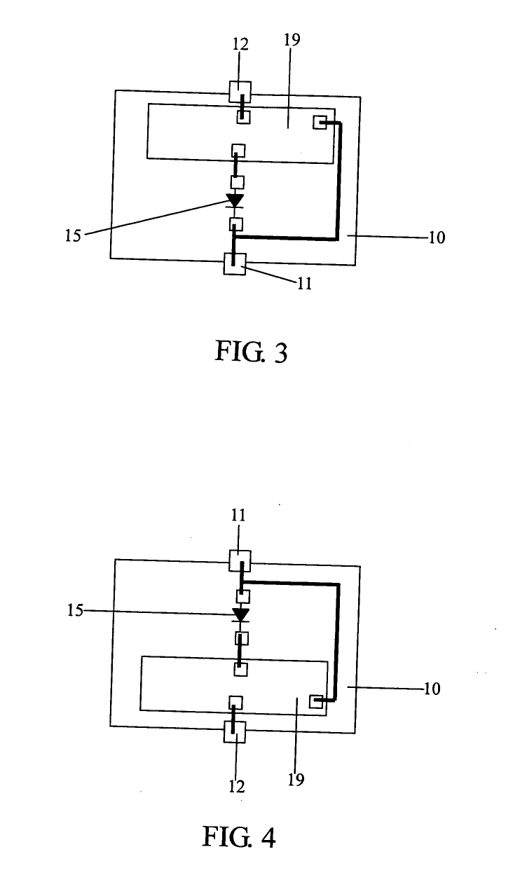

Refer to FIGS. 3 and 4, which show electrical connection of the first and the second embodiments in accordance with the present invention. The LED die 15 includes two electrode contacts, one of which is connected to the first terminal 11 of the light-emitting device 10 by means of PCB and wire bonding. The contact of the current-driving IC chip 19 is connected to the second terminal 12.

Another electrode contact of the LED die 15 is connected to a current output port of the current-driving IC chip 19. The current output of the current-driving IC chip 19 is constant and can be preset based on characteristics of the LED 15, even though deviation of forward voltage exists. Accordingly, the current input and brightness for the LED die 15 can be adjusted.

As shown in FIG. 3, the first feature of this embodiment is that the cathode contact of the LED die 15 is connected to a common node by means of PCB and wire-bonding. This common node is further connected to the first terminal 11 of the light-emitting device 10.

Another feature of the first embodiment is that the anode contact of the LED die 15 is connected to the current output port of the current-driving IC chip 19, whereby the LED 15 can be lit when a voltage or current is offered.

A further feature of this embodiment is that the contact of the current-driving IC chip 19 is connected to the second terminal 12 of the light-emitting device 10 by means of PCB and wire-bonding.

FIG. 4 shows the second embodiment, in which the anode contact the LED die 15 is connected to a common node by means of PCB and wire-bonding. This common node is further connected to the first terminal 11 of the light-emitting device 10.

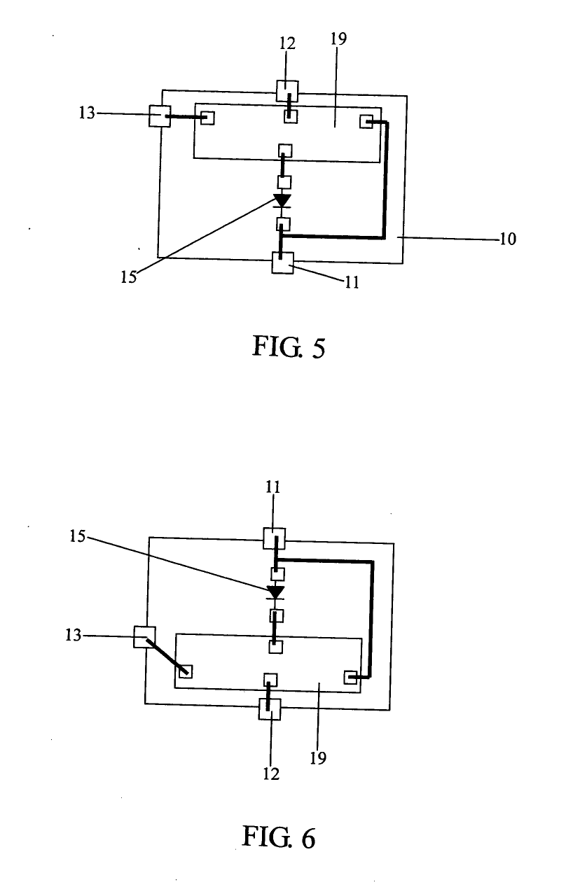

FIG. 5 shows the third embodiment, which is different from the first embodiment by increasing a third terminal 13 on the light-emitting device 10. The terminal 13 is connected to an additional contact of the current-driving IC chip 19 by means of PCB and wire-bonding. The terminal 13 principally provides a voltage or current for controlling the current output of the current-driving IC chip 19, which will vary brightness of the LED 15.

FIG. 6 shows the fourth embodiment, which is different from the second embodiment by increasing a third terminal 13 on the light-emitting device 10. The terminal 13 is connected to an additional contact of the current-driving IC chip 19 by means of PCB and wire-bonding. The terminal 13 principally provides a voltage or current for controlling the current output of the current-driving IC chip 19, which will vary brightness of the LED 15.

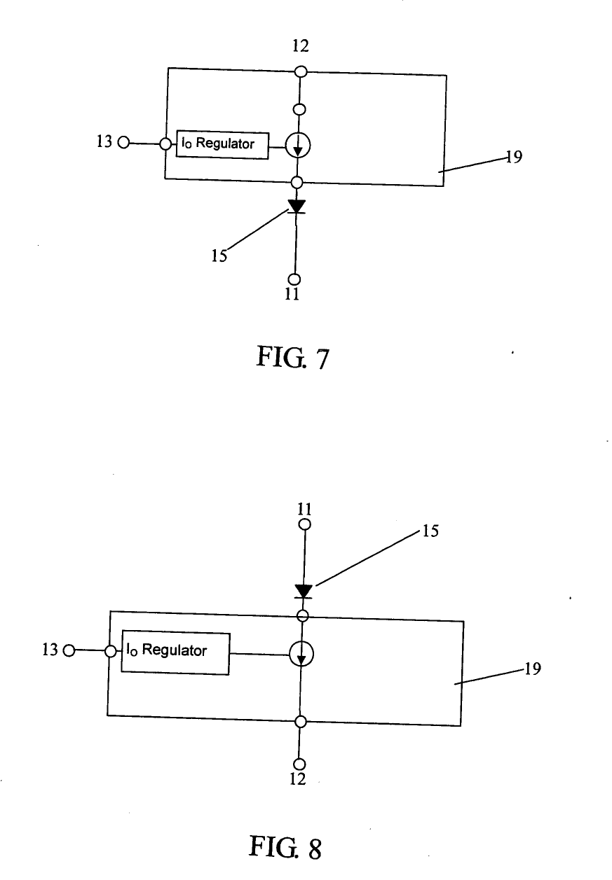

FIGS. 7 and 8 are block diagrams of the circuits respectively shown in FIGS. 5 and 6. The output port of the current-driving IC chip 19 is connected to the anodes (cathodes) of the LED die 15 so as to drive the LED 15.

In accordance with the present invention, the intellectual current-driving IC provides a constant and preset current to precisely control brightness of the LED. In other words, disadvantages of the prior light-emitting devices, such as deviation of forward voltages of the LEDs, can be overcome. Moreover, the driver IC is sized small enough to be packaged with surface-mount technology (SMT) and pin-through-hole technology (PTH), both single inline package (SIP) and dual inline package (DIP).

1. A light-emitting semiconductor device, comprising:
at least two terminals;
at least one LED die, and each comprising two electrode contacts;
a driver IC chip comprising a contact and at least one output port;
a substrate attached beneath said LED die and said driver IC chip; and
a refractive encapsulation material for integrally encapsulating and protecting said LED die and said driver IC chip;
wherein:
one of said electrode contacts of each LED die is connected to the respective output port of said driver IC chip;
another electrode contact of each LED die is connected to one of said terminals of said light-emitting semiconductor device;
said contact of said driver IC chip is connected to another terminal of said light-emitting semiconductor device;
said LED die is lit by applying voltage or current to said terminals of said light-emitting semiconductor device and passing through said driver IC chip; and
said light-emitting semiconductor device is attached on an application circuit board by adhering said terminals thereon with surface-mount technology.

2. The light-emitting semiconductor device as claimed in claim 1, wherein said driver IC chip is a current-driving IC chip and outputs a current to said LED die.

3. The light-emitting semiconductor device as claimed in claim 2, wherein said driver IC chip outputs a constant current unaffected by deviation of forward voltage of said LED die so as to precisely control brightness of said LED die.

4. A light-emitting semiconductor device, comprising:
at least three terminals;
at least one LED die, and each comprising two electrode contacts;
a driver IC chip comprising at least two contacts and at least one output port;
a substrate attached beneath said LED die and said driver IC chip; and
a refractive encapsulation material for integrally encapsulating and protecting said LED die and said driver IC chip;
wherein:
one of said electrode contacts of each LED die is connected to the respective output port of said driver IC chip by an electrically conducting means;
another electrode contact of each LED die is connected to one of said terminals of said light-emitting semiconductor device;
two contacts of said driver IC chip are respectively connected to another two terminals of said light-emitting semiconductor device, and one of said terminals provides a voltage or current for controlling output of said driver IC chip;
said LED die is lit by applying voltage or current to said terminals of said light-emitting semiconductor device and passing through said driver IC chip; and
said light-emitting semiconductor device is attached on an application circuit board by adhering said terminals thereon with surface-mount technology or through-hole. technology.

5. The light-emitting semiconductor device as claimed in claim 4, wherein said driver IC chip is a current-driving IC chip and outputs a current to said LED die.

6. The light-emitting semiconductor device as claimed in claim 5, wherein said driver IC chip outputs a constant current unaffected by deviation of forward voltage of said LED die so as to precisely control brightness of said LED die.
